(19) United States
(12) Patent Application Publication
(10) Pub. No.: US 2024/0347416 A1
(43) Pub. Date: Oct. 17, 2024

(54) HEATSINK-INTEGRATED CERAMIC SUBSTRATE AND METHOD FOR MANUFACTURING SAME

(71) Applicant: AMOSENSE CO., LTD., Cheonan-si, Chungcheongnam-do (KR)

(72) Inventor: Jihyung LEE, Cheonan-si (KR)

(73) Assignee: AMOSENSE CO., LTD., Cheonan-si, Chungcheongnam-do (KR)

(21) Appl. No.: 18/293,022

(22) PCT Filed: Jul. 25, 2022
(86) PCT No.: PCT/KR2022/010854

§ 371 Date: Jan. 29, 2024

(30) Foreign Application Priority Data
Jul. 27, 2021 (KR) 10-2021-0098312

(51) Int. Cl. H01L 23/373; H01L 21/48; H01L 23/473

(52) U.S. Cl. CPC H01L 23/3735; H01L 21/4807; H01L 23/473

(57) ABSTRACT

The present invention relates to a heatsink-integrated ceramic substrate and a method for manufacturing same, the heatsink-integrated ceramic substrate comprising: a ceramic substrate including metal layers on the upper and lower surfaces of a ceramic base; and a heatsink bonded to one surface of a metal layer, wherein the heatsink may include a flat portion having one surface in contact with the metal layer, and a plurality of heat dissipation fins formed to protrude from the other surface of the flat portion to be spaced apart from each other and contacting a liquid-type refrigerant.

### TECHNICAL FIELD

The present disclosure relates to a heat sink-integrated ceramic substrate and a method of manufacturing the same, and more specifically, to a heat sink-integrated ceramic substrate, which has a bonding structure of a heat sink provided with a plurality of heat dissipation fins for water-cooled heat dissipation and a ceramic substrate, and a method of manufacturing the same.

### BACKGROUND ART

In general, electric vehicles require an inverter for converting a direct current voltage provided from a high-voltage battery into an alternating current three-phase voltage to drive a motor.

This inverter is assembled with a power module for adjusting a high voltage of a driving battery to a state suitable for the motor and supplying the adjusted voltage. The power module includes a semiconductor chip for converting conversion, and the semiconductor chip generates high temperature heat due to a high-voltage and high-current operation. When this heat continues, there is a problem in that the semiconductor chip deteriorates, and the performance of the power module deteriorates.

In order to solve this, a heat sink is provided on at least one surface of a ceramic or metal substrate to prevent a deterioration phenomenon of the semiconductor chip due to heat through a heat-dissipation function of the heat sink.

The heat sink is made of a metal material with a high thermal conductivity, such as copper and aluminum, and since the heat sink made of a metal also has a limit in heat dissipation, when heat exceeding the limit or more is generated, cooling efficiency is degraded rapidly, causing a failure.

In addition, there is a problem in that the characteristics of the substrate on which the semiconductor chip is mounted are degraded due to the occurrence of bending or the like caused by heat.

### SUMMARY OF INVENTION

### Technical Problem

The present disclosure has been made in efforts to solve the problems and is directed to providing a heat sink-integrated ceramic substrate capable of effectively dissipating heat generated from a semiconductor chip, and a method of manufacturing the same.

### Solution to Problem

In order to achieve the object, a heat sink-integrated ceramic substrate according to an embodiment of the present disclosure includes a ceramic substrate including a metal layer provided on upper and lower surfaces of a ceramic base, and a heat sink bonded to one surface of the metal layer, wherein the heat sink includes a flat portion having one surface in contact with the metal layer, and a plurality of heat dissipation fins formed to protrude from the other surface of the flat portion at intervals and in contact with liquid refrigerant. A material of the heat sink may be any one of Cu, Al, and a Cu alloy.

A volume ratio obtained by dividing a total volume of the plurality of heat dissipation fins by a total volume of the flat portion may be in a range of 0.9 to 1.1. Here, thicknesses of the plurality of heat dissipation fins may be formed to be greater than a thickness of the flat portion.

The plurality of heat dissipation fins may be disposed in an external refrigerant circulation unit, and the liquid refrigerant circulating through the refrigerant circulation unit may exchange heat with the plurality of heat dissipation fins. The plurality of heat dissipation fins may be provided in at least one shape of a quadrangular pillar, a cylinder, a polygonal pillar, a teardrop shape, or a diamond shape.

The heat sink-integrated ceramic substrate may further include a bonding layer disposed between the metal layer of the ceramic substrate and the flat portion of the heat sink, wherein the bonding layer may be made of a material including at least one of Ag, AgCu, and AgCuTi.

A method of manufacturing a heat sink-integrated ceramic substrate according to an embodiment of the present disclosure includes preparing a ceramic substrate including a metal layer provided on upper and lower surfaces of a ceramic base, preparing a heat sink provided with a flat portion and a plurality of heat dissipation fins, and bonding one surface of the metal layer to one surface of the flat portion, wherein in the preparing the heat sink, the plurality of heat dissipation fins are formed to protrude from the other surface of the flat portion at intervals and provided in contact with liquid refrigerant.

In the preparing the heat sink, a volume ratio obtained by dividing a total volume of the plurality of heat dissipation fins by a total volume of the flat portion may be in a range of 0.9 to 1.1.

The bonding may include an arranging a bonding layer between the one surface of the metal layer and the one surface of the flat portion, and brazing the one surface of the metal layer to the one surface of the flat portion by melting the bonding layer.

The arranging the bonding layer may include an arranging the bonding layer having a thickness of 0.005 or more and 1.0 mm or less by any one method of plating, paste application, and foil attachment. In addition, in the arranging the bonding layer, the bonding layer may be made of a material including at least one of Ag, AgCu, and AgCuTi.

### Advantageous Effects of Invention

According to the present disclosure, by providing the flap portion and the plurality of heat dissipation fins and integrally brazing the heat sink with high thermal conductivity to the metal layer of the ceramic substrate, it is possible to suppress the bending phenomenon caused by the difference in volumes between the upper and lower metal layers of the ceramic substrate.

In addition, according to the present disclosure, by controlling the volume ratio of the flat portion and the plurality of heat dissipation fins in the heat sink to be within the specific range, it is possible to suppress the bending phenomenon due to the brazing.

In addition, according to the present disclosure, since the plurality of heat dissipation fins have the water-cooled heat dissipation structure in which the plurality of heat dissipation fins are cooled by being in direct contact with the consecutively circulating liquid refrigerant, it is possible to absorb and dissipate heat quickly by varying the flow rate of the liquid refrigerant and maximize the heat dissipation effect compared to the conventional air-cooled heat dissipation structure.

In addition, according to the present disclosure, by forcibly cooling the plurality of heat dissipation fins by the consecutively circulating liquid refrigerant even when the high temperature heat is generated from the semiconductor chip and the like, it is possible to prevent the overheating of the ceramic base and maintain the ceramic substrate at the constant temperature to prevent the deterioration of the semiconductor chip.

In addition, according to the present disclosure, since the liquid refrigerant is provided to flow between the plurality of heat dissipation fins, it is possible to easily control the flow rate, cooling efficiency, and the like of the liquid refrigerant as the shapes, number, and arrangement form of plurality of heat dissipation fins change.

### BRIEF DESCRIPTION OF DRAWINGS

FIG. 1 is a side view illustrating a heat sink-integrated ceramic substrate according to an embodiment of the present disclosure.

FIG. 2 is a perspective view illustrating the heat sink-integrated ceramic substrate according to the embodiment of the present disclosure.

FIG. 3 is an exploded perspective view illustrating the heat sink-integrated ceramic substrate according to the embodiment of the present disclosure.

FIG. 4 is a rear view illustrating the heat sink-integrated ceramic substrate according to the embodiment of the present disclosure.

FIG. 5 is a conceptual diagram illustrating a configuration in which the heat sink-integrated ceramic substrate according to the embodiment of the present disclosure is mounted on a refrigerant circulation unit and a circulation driving unit is connected to the refrigerant circulation unit.

FIG. 6 is a flowchart illustrating a method of manufacturing the heat sink-integrated ceramic substrate according to the embodiment of the present disclosure.

### DESCRIPTION OF EMBODIMENTS

Hereinafter, embodiments of the present disclosure will be described in detail with reference to the accompanying drawings.

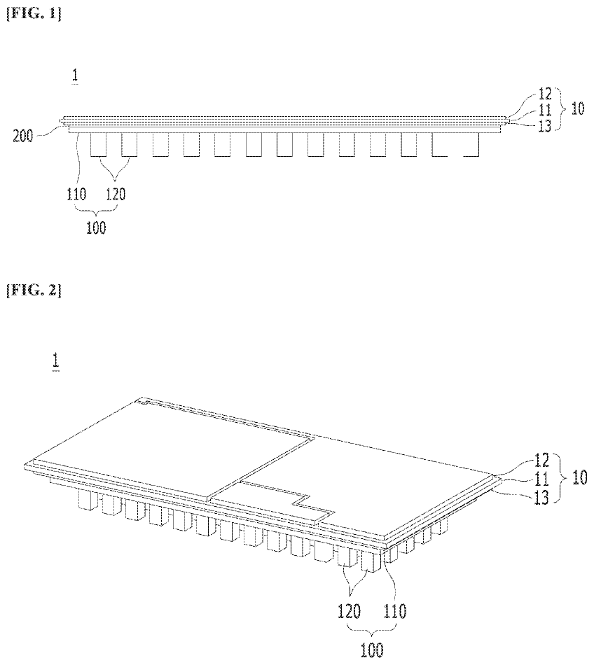

FIG. 1 is a side view illustrating a heat sink-integrated ceramic substrate according to an embodiment of the present disclosure.

As illustrated in FIG. 1, a heat sink-integrated ceramic substrate 1 according to an embodiment of the present disclosure may be provided in an integrated form including a ceramic substrate 10 and a heat sink 100.

The ceramic substrate 10 may be any one of an active metal brazing (AMB) substrate, a direct bonded copper (DBC) substrate, and a thick printing copper (TPC) substrate. These substrates are substrates in which a metal is directly bonded to a ceramic base. In the embodiment of the present disclosure, the ceramic substrate 10 may include a ceramic base 11, and an upper metal layer 12 and a lower metal layer 13 provided on upper and lower surfaces of the ceramic base 11 in order to increase the heat dissipation efficiency of heat generated from a semiconductor chip.

The ceramic base 11 may be made of an oxide-based or nitride-based ceramic material. For example, the ceramic base 11 may be any one of alumina (Al₂O₃)//, AlN, SiN, Si₃N₄, and zirconia toughened alumina (ZTA), but is not limited thereto.

For example, the upper metal layer 12 and the lower metal layer 13 may be made of one of Cu, Al, and a Cu alloy with excellent thermal conductivity. When the upper metal layer 12 and lower metal layer 13 are formed on the upper and lower surfaces of the ceramic base 11, differences in areas and thicknesses of the upper metal layer 12 and lower metal layer 13 may occur depending on design patterns. When this difference exceeds a predetermined ratio, a phenomenon in which the ceramic substrate 1 is bent occurs in a high temperature environment. According to empirical data, when a volume ratio of the upper metal layer 12 and the lower metal layer 13 is in a range of 0.75 to 0.85, a degree of bending exceeds 0.4% and thus it is inevitably discarded as defective.

In order to solve the above problem, according to the present disclosure, since the heat sink 100 is integrally brazed to the lower metal layer 13 of the ceramic substrate 10, there is an advantage in that it is possible to suppress the bending phenomenon caused by the difference in volume of the upper and lower metal layers 12 and 13, and since the ceramic substrate has not only a direct cooling structure but also a water-cooled heat dissipation structure, it is possible to maximize the heat dissipation performance.

The heat sink 100 may include a flat portion 110 in contact with one surface of the lower metal layer 13, and a plurality of heat dissipation fins 120 formed to protrude from the other surface 112 of the flat portion 110 at intervals. As will be described below, the plurality of heat dissipation fins 120 may be provided to be in direct contact with liquid refrigerant.

The heat sink 100 may be made of a material with high thermal conductivity, such as Cu, Al, or a Cu alloy, for heat dissipation. Since Cu with high thermal conductivity has a thermal expansion coefficient of 17 ppm/K, bending due to thermal expansion in a high temperature environment such as brazing may occur, thereby degrading a heat dissipation function. When this bending occurs, heat transfer between the ceramic substrate 10 and the heat sink 100 does not occur properly.

Therefore, the present disclosure is characterized by adjusting a volume ratio of the flat portion 110 and the plurality of heat dissipation fins 120 to be within a specific range in order to minimize bending when the ceramic substrate 10 and the heat sink 100 are brazed. Specifically, the heat sink 100 is preferably designed so that a volume ratio obtained by dividing the total volume of the plurality of heat dissipation fins 120 by the total volume of the flat portion 110 is in a range of 0.9 to 1.1, and more preferably designed so that the volume ratio is close to 1.0 in order to minimize bending. In this case, since the total volume is calculated by multiplying the total area by the thickness, when the total area of the plurality of heat dissipation fins 120 and the total area of the flat portion 110 are different, the thickness may be adjusted so that the volume ratio is in a range of 0.9 to 1.1. In other words, since the total area of the plurality of heat dissipation fins 120 spaced apart from each other with a space interposed therebetween is smaller than the total area of the flat portion 110, when the thicknesses are the same, the volume may differ by about four times or more. Therefore, it is preferable that the thicknesses (heights) of the plurality of heat dissipation fins 120 be formed to be greater than the thickness of the flat portion 110.

As described above, according to the present disclosure, since the ceramic substrate is manufactured so that the volume ratio of the flat portion 110 disposed on an upper portion of the heat sink 100 boned integrally with the ceramic substrate 10 and the plurality of heat dissipation fins 120 disposed on a lower portion thereof is within the specific range, it is possible to suppress the bending phenomenon due to the brazing.

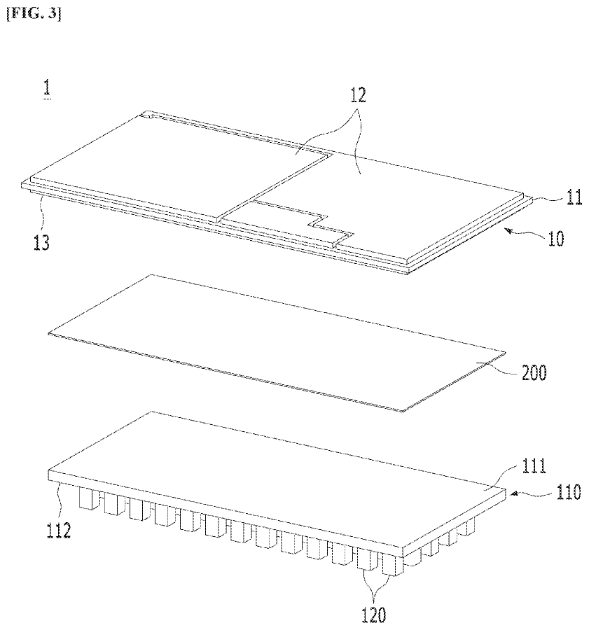

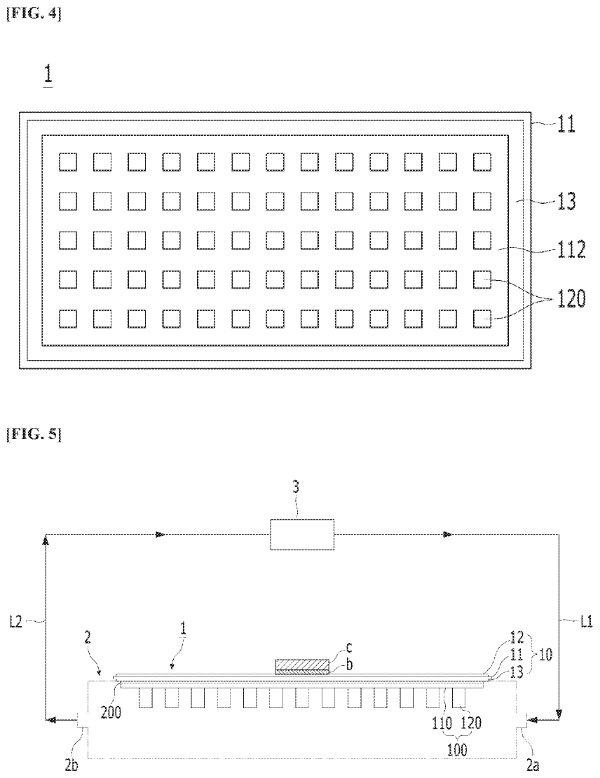

FIG. 2 is a perspective view illustrating the heat sink-integrated ceramic substrate according to the embodiment of the present disclosure, FIG. 3 is an exploded perspective view illustrating the heat sink-integrated ceramic substrate according to the embodiment of the present disclosure, and FIG. 4 is a rear view illustrating the heat sink-integrated ceramic substrate according to the embodiment of the present disclosure.

As illustrated in FIGS. 2 to 4, the upper metal layer 12 may be formed on an upper surface of the ceramic base 11 and provided in a shape of a circuit pattern. For example, the upper metal layer 12 may be formed as an electrode pattern in a region in which the semiconductor chip or nearby components are mounted. Here, a semiconductor chip c (see FIG. 5) may be a semiconductor chip formed of SiC, GaN, Si, a light emitting diode (LED), a vertical cavity surface emitting laser (VCSEL), or the like. The semiconductor chip c may be bonded to an upper surface of the upper metal layer 12 in the form of a flip chip by a bonding layer b containing solder or Ag paste.

The lower metal layer 13 may be formed on a lower surface of the ceramic base 11 and provided in a flat plate to facilitate heat transfer. Since a difference in volumes between the flat lower metal layer 13 and the total volume of the upper metal layer 12 formed as an electrode pattern is large, the bending phenomenon of the ceramic substrate 10 may occur in a high temperature environment. Therefore, according to the present disclosure, by integrally brazing the heat sink 100 including the flat portion 110 and the plurality of heat dissipation fins 120 to the ceramic substrate 10, it is possible to suppress the bending phenomenon caused by the difference in volumes between the upper and lower metal layers 12 and 13.

The flat portion 110 may have one surface 111 in direct contact with one surface of the lower metal layer 13 and may be formed in a flat shape in order to maximize a bonding area with the lower metal layer 13 to increase a bonding strength. The plurality of heat dissipation fins 120 may be formed to protrude from the other surface 112 of the flat portion 110 at intervals. In the present embodiment, although an example in which the plurality of heat dissipation fins 120 have a quadrangular pillar shape, the present disclosure is not limited thereto, and the plurality of heat dissipation fins 120 may be provided in various shapes such as a cylinder, a polygonal pillar, a teardrop shape, and a diamond shape. The shape of the heat dissipation fin can be implemented through mold machining, etching machining, milling machining, and other machining.

FIG. 5 is a conceptual diagram illustrating a configuration in which the heat sink-integrated ceramic substrate according to the embodiment of the present disclosure is mounted on a refrigerant circulation unit and a circulation driving unit is connected to the refrigerant circulation unit.

As illustrated in FIG. 5, the plurality of heat dissipation fins 120 may be disposed in a refrigerant circulation unit 2. The refrigerant circulation unit 2 may include an inlet 2a through which liquid refrigerant flows, an outlet 2b through which the liquid refrigerant is discharged, and an internal flow path (not illustrated) from the inlet 2a to the outlet 2b. In this case, the liquid refrigerant introduced through the inlet 2a of the refrigerant circulation unit 2 may be discharged through the outlet 2b after passing through the internal flow path. Since a shape and size of the internal flow path, which is a path through which the liquid refrigerant flows between the inlet 2a and the outlet 2b, may be designed variously, detailed description of the internal flow path of the refrigerant circulation unit 2 will be omitted.

The circulation driving unit 3 may be connected to the refrigerant circulation unit 2 and may circulate the liquid refrigerant using a driving force of a pump (not illustrated). Here, the inlet 2a of the refrigerant circulation unit 2 may be connected to the circulation driving unit 3 through a first circulation line L1, and the outlet 2b of the refrigerant circulation unit 2 may be connected to the circulation driving unit 3 through a second circulation line L2. In other words, the circulation driving unit 3 may consecutively circulate the liquid refrigerant along a circulation path including the first circulation line L1, the refrigerant circulation unit 2, and the second circulation line L2. Here, the liquid refrigerant may be deionized water, but is not limited thereto, and may use liquid nitrogen, alcohol, or other solvents if necessary.

The liquid refrigerant supplied from the circulation driving unit 3 may flow into the inlet 2a of the refrigerant circulation unit 2 through the first circulation line L1, discharged through the outlet 2b by moving along the internal flow path formed in the refrigerant circulation unit 2, and then may flow back to the circulation driving unit 3 through the second circulation line L2. Although not illustrated in detail, the circulation driving unit 3 may include a heat exchanger (not illustrated). The heat exchanger of the circulation driving unit 3 may decrease a temperature of the liquid refrigerant of which a temperature has increased while passing through the internal flow path of the refrigerant circulation unit 2, and the circulation driving unit 3 may supply the liquid refrigerant of which the temperature has been decreased by the heat exchanger back to the first circulation line L1 using the driving force of the pump.

As described above, the refrigerant circulation unit 2 may be provided so that the liquid refrigerant supplied from the circulation driving unit 3 circulates consecutively. In this case, the plurality of heat dissipation fins 120 may be disposed in the internal flow path of the refrigerant circulation unit 2 and provided to exchange heat by being in direct contact with the liquid refrigerant consecutively circulating along the internal flow path. In other words, the plurality of heat dissipation fins 120 have a water-cooled heat dissipation structure that may be directly cooled by the consecutively circulating liquid refrigerant.

By forcibly cooling the plurality of heat dissipation fins 120 by the consecutively circulating liquid refrigerant even when high-temperature heat is generated from the semiconductor chip c, it is possible to prevent the overheating of the ceramic substrate 10 and maintain the ceramic substrate at the constant temperature to prevent the deterioration of the semiconductor chip c. In other words, since the temperature of the liquid refrigerant circulating along the internal flow path of the refrigerant circulation unit 2 is about 25° C. even when the high temperature heat of about 100° C. or higher is generated, it is possible to quickly cool the heat transferred to the plurality of heat dissipation fins 120.

Conventionally, the base plate for heat dissipation is bonded to the ceramic substrate by soldering or Ag sintering, and since soldering paste such as an Ag epoxy or Ag sintering film used at this time has low thermal conductivity of about 110 W/m·K, there is a problem in that cooling efficiency is degraded, and since a process of being coated with a thermal interface materials (TIM) material such as graphite should be additionally performed, there is a problem in that the manufacturing process is complicated.

Meanwhile, according to present disclosure, since the heat sink 100 including the flat portion 110 and the plurality of heat dissipation fins 120 is brazed and a material such as Ag, AgCu, or AgCuTi used upon brazing has thermal conductivity of about 350 W/m·K or more, it is possible to maximize the heat dissipation effect due to the thermal conductivity that is about 4 times higher than that of the conventional one. In addition, it is possible to simplify the process compared to the conventional one and save energy and costs.

In addition, since the heat sink-integrated ceramic substrate 1 according to the embodiment of the present disclosure has a configuration in which the heat sink 100 having a pin-fin structure and the ceramic substrate 10 are integrated and has a structure that may directly cool the heat generated from the semiconductor chip c, it is possible to not only achieve weight reduction and miniaturization, but also improve heat dissipation performance.

In addition, since the heat sink-integrated ceramic substrate 1 according to the embodiment of the present disclosure has the water-cooled heat dissipation structure, it is possible to quickly absorb and dissipate heat by varying the flow rate of the liquid refrigerant, thereby maximizing the heat dissipation effect compared to the conventional air-cooled heat dissipation structure.

The shapes, number, and arrangement form of plurality of heat dissipation fins 120 may be changed variously according to preliminary simulation results during design. Since the liquid refrigerant flows between the plurality of heat dissipation fins 120, the flow rate, cooling efficiency, and the like of the liquid refrigerant can be easily controlled by changing the shapes, number, and arrangement form of plurality of heat dissipation fins 120.

Meanwhile, although not illustrated, the ceramic substrate 10 and the heat sink 100 may be bonded by a bonding layer 200. In this case, the bonding layer 200 may be made of a material containing at least one of Ag, AgCu, and AgCuTi. Ag, AgCu, and AgCuTi may function to increase the bonding strength due to the high thermal conductivity and at the same time, facilitate heat transfer to increase the heat-dissipation efficiency. The bonding layer 200 may be formed by any one method of plating, paste application, and foil attachment and may have a thickness of about 0.005 to 1.0 mm. The bonding layer 200 may be disposed between the lower metal layer 13 of the ceramic substrate 10 and the flat portion 110 of the heat sink 100 and may integrally bond the ceramic substrate 10 to the heat sink 100 at a brazing temperature. The brazing temperature may be in a range of 800 to 950° C. The brazing is to bond base materials by permeating and diffusing the bonding layer 200 between the base materials to be bonded after melting only the bonding layer 200 at temperatures of melting points or less of the base materials using a wetting phenomenon, a capillary phenomenon, and the like and has excellent bonding reliability due to an excellent bonding strength compared to general welding bonding or the like.

Meanwhile, the ceramic substrate 10 and the heat sink 100 may be brazed after being temporarily bonded through thermochemical bonding. In this case, the thermochemical bonding may be bonding using heat fusion, an adhesive, an gluing agent, or the like. As described above, the ceramic substrate 10 and the heat sink 100 may be airtightly bonded by the bonding method such as the brazing or the thermochemical bonding and have a high bonding strength capable of withstanding a water pressure, a hydraulic pressure, or the like.

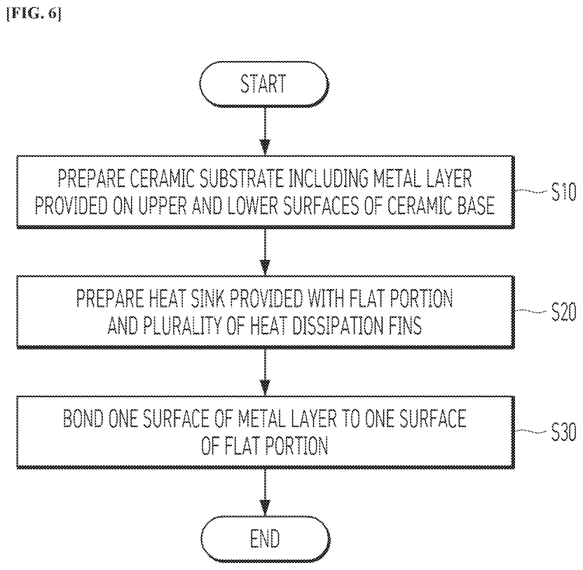

FIG. 6 is a flowchart illustrating a method of manufacturing the heat sink-integrated ceramic substrate according to the embodiment of the present disclosure.

As illustrated in FIG. 6, a method of manufacturing the ceramic substrate according to the embodiment of the present disclosure may include preparing the ceramic substrate 10 including the metal layers 12 and 13 provided on the upper and lower surfaces of the ceramic base 11 (S10), preparing the heat sink 100 provided with the flat portion 110 and the plurality of heat dissipation fins 120 (S20), and bonding one surface of the metal layer 13 to one surface 111 of the flat portion 110 (S30). Here, the preparing of the ceramic substrate 10 (S10) and the preparing of the heat sink 100 (S20) may be performed sequentially or performed in a changed order and performed substantially at the same time.

In the preparing of the ceramic substrate 10 (S10), the ceramic substrate 10 may be any one of an AMB substrate, a DBC substrate, and a TPC substrate. Here, the ceramic substrate 10 may include the ceramic base 11, and the upper metal layer 12 and the lower metal layer 13 provided on the upper and lower surfaces of the ceramic base 11 in order to increase the heat dissipation efficiency of heat generated from the semiconductor chip.

In the preparing of the heat sink 100 (S20), the heat sink 100 may be made of a material, such as Cu, Al, and a Cu alloy, with high thermal conductivity and may include the flat portion 110 and the plurality of heat dissipation fins 120. The flat portion 110 is a portion in which one surface 111 comes into contact with the lower metal layer 13 and may be provided in a flat shape in order to maximize the bonding area. The plurality of heat dissipation fins 120 may be formed to protrude from the other surface 112 of the flat portion 110 at intervals. The plurality of heat dissipation fins 120 may be disposed in the external refrigerant circulation unit 2 (see FIG. 5) and may be provided to be in direct contact with the liquid refrigerant circulating through the refrigerant circulation unit 2.

The plurality of heat dissipation fins 120 may be provided in at least one shape of a quadrangular pillar, a cylinder, a polygonal pillar, a teardrop shape, or a diamond shape, and various shapes can be implemented through mold machining, etching machining, milling machining, or other machining. In the present embodiment, although an example in which the plurality of heat dissipation fins 120 are formed in the preparing of the heat sink 100 is described, the plurality of heat dissipation fins 120 may be formed after the bonding (S30). For example, the plurality of heat dissipation fins 120 may be formed by preparing the heat sink 100 having a thick flat shape, bonding the heat sink 100 to the lower metal layer 13 of the ceramic substrate 10, and then removing a portion of the heat sink 100 by etching machining, milling machining, or the like.

In addition, in the preparing of the heat sink 100 (S20), the volume ratio obtained by dividing the total volume of the plurality of heat dissipation fins 120 by the total volume of the flat portion 110 may be in a range of 0.9 to 1.1. Since the plurality of heat dissipation fins 120 are disposed to be spaced apart from each other with a space therebetween, when the volume difference with the flat portion 110 formed of a flat plate is large, the bending phenomenon occurs in a high temperature environment. Therefore, according to the present disclosure, the thickness of the plurality of heat dissipation fins 120 is formed to be greater than the thickness of the flat portion 110, and the volume ratio of the plurality of heat dissipation fins 120 and the flat portion 110 is controlled to be in a range of 0.9 to 1.1, and thus it is possible to suppress the bending phenomenon caused by the volume difference.

The bonding the one surface of the metal layer 13 to the one surface 111 of the flat portion 110 (S30) may include an arranging the bonding layer 200 (S31) and brazing (S32).

In the arranging the bonding layer 200 (S31), the bonding layer 200 having a thickness of 0.005 mm or more and 1.0 mm or less may be disposed by any one method of plating, paste application, and foil attachment. In this case, the bonding layer 200 may be disposed between the one surface of the lower metal layer 13 and the one surface 111 of the flat portion 110. The bonding layer 200 may be made of a material containing at least one of Ag, AgCu, and AgCuTi.

After the arranging the bonding layer 200 (S31), the brazing the one surface of the metal layer 13 to the one surface 111 of the flat portion 110 by melting the bonding layer 200 (S32) may be performed. In the brazing (S32), the bonding layer 200 interposed between the one surface of the lower metal layer 13 and the one surface 111 of the flat portion 110 may be bonded by melting the bonding layer 200 at 800 to 950° C., and at this time, top weight or pressing may be applied to increase the bonding strength.

As described above, according to the present disclosure, since the heat sink is brazed to the ceramic substrate, and the heat sink is brazed by the bonding layer containing at least one of Ag, AgCu, and AgCuTi, it is possible to maximize the heat dissipation effect due to the thermal conductivity that is about 4 times higher than the conventional one.

In addition, according to the present disclosure, since the heat sink with the pin-fin structure and the ceramic substrate are integrated and the above structure has a structure that may directly cool the heat generated from the semiconductor chip, it is possible to not only achieve weight reduction and miniaturization but also improve heat dissipation performance.

The best embodiments of the present disclosure have been disclosed in the drawings and the specification. Here, although specific terms are used, they are used only for the purpose of describing the present disclosure and are not used to limit the meaning or scope of the present disclosure described in the claims. Therefore, those skilled in the art will understand that various modifications and equivalent embodiments are possible from the present disclosure. Therefore, the true technical scope of the present disclosure should be determined by the technical spirit of the appended claims.

1. A heat sink-integrated ceramic substrate comprising:
a ceramic substrate including a metal layer provided on upper and lower surfaces of a ceramic base; and
a heat sink bonded to one surface of the metal layer,
wherein the heat sink includes:
a flat portion having one surface in contact with the metal layer; and
a plurality of heat dissipation fins formed to protrude from the other surface of the flat portion at intervals and in contact with liquid refrigerant.

2. The heat sink-integrated ceramic substrate of claim 1, wherein a volume ratio obtained by dividing a total volume of the plurality of heat dissipation fins by a total volume of the flat portion is in a range of 0.9 to 1.1.

3. The heat sink-integrated ceramic substrate of claim 1, wherein thicknesses of the plurality of heat dissipation fins are greater than a thickness of the flat portion.

4. The heat sink-integrated ceramic substrate of claim 1, wherein the plurality of heat dissipation fins are disposed in an external refrigerant circulation unit, and
the liquid refrigerant circulating through the refrigerant circulation unit exchanges heat with the plurality of heat dissipation fins.

5. The heat sink-integrated ceramic substrate of claim 1, wherein the plurality of heat dissipation fins are provided in at least one shape of a quadrangular pillar, a cylinder, a polygonal pillar, a teardrop shape, or a diamond shape.

6. The heat sink-integrated ceramic substrate of claim 1, wherein a material of the heat sink is any one of Cu, Al, and a Cu alloy.

7. The heat sink-integrated ceramic substrate of claim 1, further comprising a bonding layer disposed between the metal layer of the ceramic substrate and the flat portion of the heat sink,
wherein the bonding layer is made of a material including at least one of Ag, AgCu, and AgCuTi.

8. A method of manufacturing a heat sink-integrated ceramic substrate, comprising:
preparing a ceramic substrate including a metal layer provided on upper and lower surfaces of a ceramic base;
preparing a heat sink provided with a flat portion and a plurality of heat dissipation fins; and
bonding one surface of the metal layer to one surface of the flat portion,
wherein in the preparing the heat sink,
the plurality of heat dissipation fins are formed to protrude from the other surface of the flat portion at intervals and provided in contact with liquid refrigerant.

9. The method of claim 8, wherein in the preparing the heat sink,
a volume ratio obtained by dividing a total volume of the plurality of heat dissipation fins by a total volume of the flat portion is in a range of 0.9 to 1.1.

10. The method of claim 8, wherein the bonding includes:
arranging a bonding layer between the one surface of the metal layer and the one surface of the flat portion; and
brazing the one surface of the metal layer to the one surface of the flat portion by melting the bonding layer.

11. The method of claim 10, wherein the arranging the bonding layer includes arranging the bonding layer having a thickness of 0.005 or more and 1.0 mm or less by any one method of plating, paste application, and foil attachment.

12. The method of claim 10, wherein in the arranging the bonding layer,
the bonding layer is made of a material including at least one of Ag, AgCu, and AgCuTi.
